(19) United States
(12) Patent Application Publication
(10) Pub. No.: US 2015/0196978 A1
(43) Pub. Date: Jul. 16, 2015

(54) SOLDER ALLOY

(71) Applicant: SUMITOMO METAL MINING CO., LTD., Tokyo (JP)

(72) Inventors: Takashi Iseki, Ome-shi (JP); Toshikazu Shimizu, Ome-shi (JP)

(21) Appl. No.: 14/416,130

(22) PCT Filed: Jul. 24, 2013
(86) PCT No.: PCT/JP2013/070122

§ 371 Date: Jan. 21, 2015

(30) Foreign Application Priority Data
Jul. 26, 2012 (JP) 2012-165344

(51) Int. Cl. B23K 35/02; B23K 35/30; B23K 35/24; C22C 12/00; H05K 1/18; C22C 11/00; C22C 13/00; C22C 13/02; C22C 5/02; C22C 28/00; B23K 35/26; C22C 11/06

(52) U.S. Cl. CPC B23K 35/0222; B23K 35/264; B23K 35/268; B23K 35/262; B23K 35/3013; B23K 35/24; C22C 12/00; C22C 11/06; C22C 11/00; C22C 13/00; C22C 13/02; C22C 5/02; C22C 28/00; H05K 1/18

(57) ABSTRACT

Disclosed herein are a solder alloy and an electronic device using the solder alloy to join electronic components. The solder alloy has virtually no limitation in its alloy composition, is excellent in wettability and joinability necessary for electronic device assembly, and thus ensures high joint reliability.

The solder alloy has an oxide layer thickness of 120 nm or less and a surface roughness (Ra) of 0.60 μm or less. The alloy composition of the solder alloy is not particularly limited, but any one of Bi, Pb, Sn, Au, In, and Zn is preferably contained as a main component.

### TECHNICAL FIELD

The present invention relates to a solder alloy that is excellent in wettability and joinability and thus ensures high joint reliability.

### BACKGROUND ART

A solder used to join electronic components is required to have high joint reliability. In order to meet this requirement, a solder needs to have excellent wettability on and joinability to a substrate or the like. Solders are roughly classified into Pb-based solders, Sn-based solders, Au-based solders, and In-based solders. While various types of these solders are used depending on the intended use, it is always necessary for these solders to meet the requirements of wettability and joinability. Under the circumstances, various efforts have been made to improve wettability etc., but as a matter of fact, many problems still remain.

For example, Patent Literatures 1 and 2 state that addition of a wettability-improving element such as Ag and an oxidation-suppressing element such as P, Ge, or Ga to a solder alloy containing Sn as a main component and Cu improves the wettability of the solder alloy. Patent Literature 3 states that a joint region of a circuit board or an electronic component is Au-plated, and a solder is melted by heating in a non-oxidizing or reducing atmosphere to expose a newly-formed surface of the solder to ensure wettability.

Patent Literature 4 discloses an Sn—Au alloy solder paste including a mixture of flux and an Sn—Au alloy solder powder having the composition of 6.5 to 9.8 mass % of Au and the balance being Sn and inevitable impurities. Patent Literature 4 states that this Sn—Au alloy solder paste has excellent wettability and forms few voids.

### CITATION LIST

### Patent Literature

### Patent Literature 1: JP 2004-154864 A

### Patent Literature 2: JP 2004-181485 A

### Patent Literature 3: JP 6-326448 A

### Patent Literature 4: JP 2008-137017 A

### SUMMARY OF INVENTION

### Technical Problem

However, Patent Literatures 1 and 2 do not clearly state how the oxidation-suppressing element or the wettability-improving element exerts its effect. The oxidizing (or reducing) property of Ge is substantially the same as that of Sn, and therefore it is unlikely that Ge improves wettability due to a redox phenomenon. P is expected to have the effect of reducing a solder etc. during melting of the solder, but a P oxide is a gas and therefore may cause void formation or poor joining in soldering. For this reason, it is impossible to understand from these Patent Literatures how P contained in the Sn—Cu-based alloy behaves to improve wettability.

Patent Literature 3 does not specifically state the mechanism of exposure of a newly-formed surface of the solder or the control of an atmosphere in soldering. Further, an oxide film on the surface of the solder formed during production of the solder cannot be removed by the technique disclosed in Patent Literature 3. Even when a newly-formed surface of the solder is exposed by, for example, rupture of the oxide film, the oxide on the surface of the solder remains between, for example, a circuit board and an electronic component, which inevitably results in void formation or a reduction in joint strength. Patent Literature 3 does not make any reference to such an issue, but it can be said that high joint reliability cannot be achieved when the electronic component and the circuit board are joined together in a state where the oxide on the surface of the solder remains between them.

Patent Literature 4 does not clearly state a mechanism for improving wettability. Further, it is unlikely that the Sn—Au alloy solder paste having a composition within the above range has excellent wettability because it contains a larger amount of easily-oxidizable Sn and a smaller amount of non-oxidizable Au as compared to a commonly-used Au-20 mass % Sn solder. As described above, various techniques for improving wettability have been proposed, but it is still hard to say that these techniques are adequate. On the other hand, as a matter of fact, there are ever-increasing demands for replacement of high-cost paste materials, yield improvement by reducing a void ratio or improving joint stability, and improvement in joint reliability.

In view of the above-described conventional problems, it is therefore an object of the present invention to provide a solder alloy that is excellent in wettability and joinability and thus ensures high joint reliability for use in, for example, assembly of various electronic components of an electronic device and an electronic device using such a solder alloy to join electronic components.

### Solution to Problem

In order to achieve the above object, the present inventors have studied means for improving the wettability and joinability of a solder without limitations imposed by the composition of the solder. The present inventors have focused attention on the conditions of the surface of a solder, and as a result have found that the thickness of an oxide layer present on the surface of the solder and the surface roughness of the solder have a great impact on the wettability and joinability of the solder. This finding has led to the completion of the present invention.

Specifically, a solder alloy according to the present invention has an oxide layer thickness of 120 nm or less and a surface roughness (Ra) of 0.60 μm or less, and these requirements are essential. Further, the solder alloy according to the present invention preferably contains any one of Bi, Pb, Sn, Au, In, and Zn as a main component. It is to be noted that the shape of the solder alloy is not at all limited, and the solder alloy may be in the form of sheet, wire, rod, ball or fine powder for paste.

Preferred specific examples of the composition of the solder alloy according to the present invention are as follows. A first solder alloy contains Bi as a main component in an amount of 85 mass % or more.

A second solder alloy as in the first solder alloy further contains 0.01 mass % or more but 13.5 mass % or less of Zn.

A third solder alloy as in the first solder alloy further contains 0.01 mass % or more but 12.0 mass % or less of Ag.

A fourth solder alloy contains 40 mass % or more but less than 85 mass % of Bi and 60 mass % or less of Sn, wherein when an element or elements other than Bi and Sn are contained, content thereof is 5 mass % or less.

A fifth solder alloy contains Pb as a main component and at least one of Sn, Ag, Cu, In, Te, and P as a second element group, wherein a total amount of Pb and the second element group is 80 mass % or more.

A sixth solder alloy contains Sn as a main component and at least one of Ag, Sb, Cu, Ni, Ge, and P as a second element group, wherein a total amount of Sn and the second element group is 80 mass % or more.

A seventh solder alloy contains Au as a main component and at least one of Ge, Sn, and Si as a second element group, wherein a total amount of Au and the second element group is 90 mass % or more.

An eighth solder alloy contains 40 mass % or more of In and at least one of Ag, Sn, Cu, Zn, and P.

A ninth solder alloy contains Zn and Sn in a total amount of 80 mass % or more but contains no Al.

### Advantageous Effects of Invention

According to the present invention, it is possible to provide a solder alloy that is excellent in wettability and joinability and thus ensures high joint reliability with virtually no limitations imposed by the composition of the alloy. Therefore, use of the solder alloy according to the present invention for joining of electronic components makes it possible to provide an electronic component-mounted substrate or an electronic device having high reliability.

### BRIEF DESCRIPTION OF DRAWING

FIG. 1 A graph explaining the definition of the thickness of an oxide layer on the surface of a solder alloy.

### DESCRIPTION OF EMBODIMENTS

A solder is generally used to join a semiconductor element to a substrate such as a lead frame. Semiconductor packages assembled with a solder are incorporated into home electrical appliances, cars, etc., and thus they are required to have high reliability as a matter of course. In order to achieve high reliability, such semiconductor packages need to withstand heat stress or the like which are repeatedly applied due to temperature change or heat generated by the semiconductor element. In order to achieve this, the solder needs to have excellent wettability and joinability.

Wettability and joinability are properties necessary for whatever kind of solder, and are therefore one of the most important properties necessary for solders. In order to improve wettability, an oxide layer on a solder surface needs to be reduced which is common to all solders. That is, a main factor for a reduction in wettability is an oxide layer on a solder surface. When an oxide layer is present on the surface of a solder, a solder metal cannot have direct contact with a substrate metal during soldering because the oxide layer is still present even after the solder is melted, which inhibits alloy formation and prevents the solder from joining to the substrate.

A solder alloy according to the present invention is particularly excellent in wettability and joinability because the amount of an oxide per unit amount (e.g., unit weight or unit volume) of solder can be reduced by reducing the thickness of a surface oxide layer and by reducing the surface roughness. Specifically, the most distinctive feature of the solder alloy according to the present invention is that it has an oxide layer thickness of 120 nm or less and a surface roughness (Ra) of 0.60 μm or less. The alloy composition of the solder alloy is not particularly limited, but it is preferable that any one of Bi, Pb, Sn, Au, In, and Zn is contained as a main component.

It is often the case that a commonly-used conventional solder alloy is not required to have high reliability, and therefore its surface conditions, such as oxide layer thickness and surface roughness, are not strictly controlled. For example, a solder alloy is usually subjected to final rolling using a roll having a surface roughness of more than 0.3 μm, and thus some solder alloy has a surface roughness of more than 0.60 μm after molding. In another case, flaws of an extrusion molding die or a casting mold having a high surface roughness causes the surface roughness of a solder alloy of more than 0.60 μm. Still another case, no inert gas or a small amount of inert gas is introduced during melt-casting of a Pb-based solder or the like for cost saving, and thus a large amount of oxide is generated and mixed into a casting so that the thickness of an oxide layer generally exceeds 120 nm.

Hereinbelow, the solder alloy according to the present invention, specifically its surface oxide layer, surface roughness, production method, and solder composition will be described in detail.

<Oxide Layer of Solder Alloy>

The essential requirement for the solder alloy according to the present invention is that the thickness of an oxide layer is controlled to be 120 nm or less. This is because by controlling the thickness of an oxide layer to be 120 nm or less, it is possible to improve wettability and joinability and thus ensures high joint reliability.

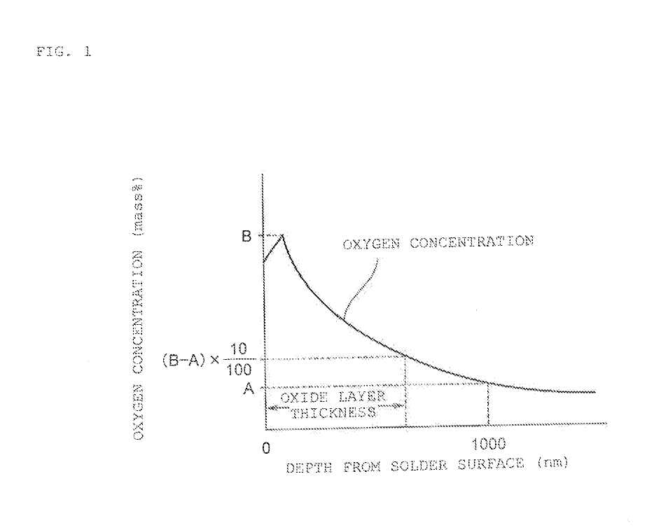

It is to be noted that as shown in FIG. 1, when the amount of oxygen at a point 1000 nm below a solder surface in a depth direction (direction perpendicular to the solder surface) is defined as A mass % and the maximum oxygen concentration between the solder surface and the point 1000 nm below the solder surface in the depth direction is defined as B mass %, the thickness of an oxide layer on the surface of the solder alloy according to the present invention is defined as a depth from the surface at which the concentration of oxygen is reduced to (B−A)×(10/100) mass %.

The major cause of a reduction in wettability or joinability is generally an oxide present between the joint surface of a substrate or an electronic component and a solder alloy matrix. Usually, metals can form an alloy as long as they are properly selected. For example, Cu that is a main component of a substrate or Ni that may be used as an uppermost layer of a substrate easily form a solid solution in a molten state with a common Pb- or Sn-based solder having no oxide layer.

However, an oxide formed on the surface of a solder alloy remains in a solid state at a soldering temperature (e.g., 200° C. to 450° C.), and therefore does not react with the metal surface of a substrate or the like. Therefore, when an oxide layer is formed on the surface of a solder, a solder metal and a substrate metal (e.g., Cu, Ni) cannot have contact with each other, and as a result, the solder cannot be joined to a substrate. On the other hand, when a solder having no oxide or having a thin oxide layer on its surface is used for joining a substrate or the like, metals can have contact with each other, and as a result, the solder can be joined to the substrate. Therefore, absence of an oxide layer on a solder surface is one of the most important requirements to improve solder wettability, which generally applies to all solder alloys.

The same also applies to Au-based solders that are believed to have the most excellent wettability. Au-based solders may also often exhibit insufficient wettability. This insufficient wettability is caused by progress of oxidation of an additive element. For example, in the case of an Au—Sn solder or Au—Ge solder famous as an Au-based alloy, Sn or Ge is oxidized and is therefore present as a surface oxide layer that reduces wettability. Au plating on the surface of an Au-based solder is commonly performed to improve wettability as one of measures for solving the problem.

As described above, the thickness of an oxide layer on the surface of the solder alloy according to the present invention is controlled to be 120 nm or less. An oxide layer significantly reduces wettability etc., but it is difficult to completely eliminate the presence of an oxide layer. In many cases, the reduction in wettability can be compensated for by, for example, adjusting soldering conditions as long as the thickness of the oxide layer is reasonably small. The thickness of an oxide layer depends on the composition of a solder, but when having a thickness of about 120 nm or less, the oxide layer breaks during soldering so that a solder molten metal flows out from the inside of the oxide layer and can have direct contact with the metal surface of a substrate, which allows joining of the solder to the substrate.

For example, when a Pb-based solder wire is supplied at high speed to a Cu substrate while the surface of the Cu substrate or the Pb-based solder wire is reduced with hydrogen using forming gas (mixed gas of hydrogen and nitrogen), an oxide layer at the tip of the solder wire is ruptured and reduced so that molten solder can be directly supplied to a Cu surface having virtually no oxide layer, and therefore the solder wire can be joined to the Cu substrate. In this way, when a solder and a substrate or the like are joined together without an oxide layer between them, the joint between them can have high joint strength and can sufficiently withstand even under severe environmental conditions which ensures excellent joint reliability.

<Surface Roughness of Solder>

In the present invention, it is essential for improving wettability and joinability and thus ensuring high joint reliability to control the thickness of an oxide layer to be 120 nm or less and to adjust solder surface roughness (Ra) to 0.60 μm or less as described above.

As already described above, a major cause of reduction in the wettability or joinability of a solder is an oxide layer, more specifically, the amount of an oxide present near the surface of the solder. That is, even when an oxide layer is thin, a rough solder surface having many surface irregularities increases the amount of an oxide present near the solder surface, which causes the same phenomenon as when the oxide layer is virtually thick so that wettability and joinability are significantly reduced.

When a solder has a high surface roughness, that is, when a solder has a rough surface, disadvantage is not only an increase in the amount of an oxide, and what is worse is that the actual area of contact between the solder and a joint surface is reduced. For example, when an electronic component and a substrate are joined together with a sheet-shaped solder, the actual area of contact has a very significant influence on wettability etc. When the solder sheet has a very low surface roughness, the area of a region where the solder and, for example, the electronic component are macroscopically overlapped is regarded as the actual area of contact between them.

However, when the solder sheet has a high surface roughness, in an extreme case, the solder and, for example, the electronic component are in point contact with each other so that the actual area of contact between them is very small. In this case, even when an oxide layer on the surface of the solder is very thin, it is difficult to form an alloy to join the solder and the electronic component or the substrate together. If the solder and the electronic component or the substrate can be partially joined together, many voids are formed due to surface irregularities. Therefore, a reduction in surface roughness leads to a reduction in voids and then to prevention of cracks or the like, and as a result, a joint having high reliability can be obtained.

In the present invention, solder surface roughness (Ra) is set to 0.60 μm or less. According to experimental results, when the surface roughness (Ra) of a solder exceeded 0.60 μm, it was difficult to achieve joining even when the thickness of an oxide layer or the composition of the solder was adjusted. Further, even when the solder was supplied while a substrate was reduced using forming gas in soldering, the solder and the substrate could not be joined together or many voids were formed. Therefore, solder surface roughness (Ra) is set to 0.60 μm or less, particularly preferably 0.30 μm or less to achieve more successful joining.

<Production Method>

In the present invention, a method for producing the solder alloy is not particularly limited per se. That is, raw materials may be melted by, for example, resistance heating, reduction diffusion, or high-frequency melting. Particularly, high-frequency melting is preferred because metals can be efficiently melted in a short time even when the metals have high melting points. However, oxygen present during melting or casting not only promotes oxidation of an alloy but also increases the thickness of an oxide layer due to mixing of an oxide layer into a casting or increases surface roughness. In order to prevent them, it is preferred that an inert gas is fed during melting and is further fed to the molten metal inlet of a mold. When a fine solder powder is produced, gas atomization or liquid atomization may be used. Alternatively, disk atomization may be used.

When formed into a sheet shape, the solder is rolled by, for example, cold rolling, warm rolling, hot rolling, or press rolling. However, warm rolling or hot rolling is likely to cause surface oxidation, and therefore needs to be performed in consideration of productivity or a desired oxide layer thickness to reduce the thickness of an oxide layer. Particularly, an Au-based solder is harder than a Pb-based solder or an Sn-based solder, and therefore it is preferred that warm rolling or hot rolling is first performed to reduce the thickness of the Au-based solder to some degree, and then cold rolling is performed. In this way, combined use of two rolling methods makes it possible to prevent cracks or burrs during rolling to improve quality, and further makes it possible to increase the speed of rolling to increase production efficiency while controlling an oxide layer.

In the present invention, since solder surface roughness (Ra) is controlled to be 0.60 μm or less, the surface roughness (Ra) of a roll used in the above-described rolling is preferably 0.30 μm or less. When two or more kinds of rolling methods, such as hot rolling and cold rolling, are used, only the reduction roll used in final rolling (finish rolling) may have a surface roughness (Ra) of 0.30 μm or less. If a reduction roll having a surface roughness (Ra) of more than 0.30 μm is used, solder surface roughness (Ra) is likely to exceed 0.60 μm, and therefore even when the thickness of an oxide layer on a solder surface is controlled to be 120 nm or less, wettability and joinability are often reduced.

When the solder is formed into a wire shape to produce a solder wire, an extrusion method or a wire drawing method may be used. For example, when an extrusion method is used to produce a solder wire, the extrusion temperature needs to be set in consideration of the composition of the solder. That is, if the extrusion temperature is high, surface oxidation easily proceeds, and on the other hand, if the extrusion temperature is too low, the solder alloy is extruded in a hard state and therefore extrusion processing requires longer time. Further, extrusion is preferably performed in an inert gas. This is because if extrusion is performed in the atmosphere, a heated wire is quickly oxidized. Further, extrusion is preferably performed under conditions as airtight as possible while an insert gas is fed.

Usually, polishing or acid-washing is not performed in the production process of solder. However, in the present invention, the solder alloy may be polished or acid-washed before, during, or after processing into a wire or sheet to reduce the thickness of an oxide layer on the surface of the solder alloy and to reduce the surface roughness of the solder alloy.

When the solder is acid-washed, the type of acid to be used is not limited, and an inorganic acid or an organic acid may be used. However, an inorganic acid that is inexpensive and is highly effective in removing oxide film is preferably used. When an inorganic acid is used, hydrochloric acid, sulfuric acid, nitric acid, phosphoric acid, or the like is preferably used. When an organic acid is used, citric acid, oxalic acid, or the like is preferably used. A weak acid is more preferably used. A strong acid may be used for washing, but depending on conditions, the solder is partially dissolved due to a high solution rate of a solder metal, and therefore the solder is likely to have a high surface roughness or partial compositional deviation is likely to occur. Therefore, it is preferred that washing is performed little by little using a weak acid in a relatively long time depending on the situation.

An acid to be used is of course selected depending on the composition of the solder, but is preferably selected with sufficient attention given to acid-washing time, acid-washing temperature, acid concentration, etc. For example, when a 5% acetic acid solution is used, acid-washing is preferably performed using the solution at 20° C. for about 15 minutes. The thickness of an oxide layer is most reduced just after immersion of the solder in an acid solution, and the amount of dissolution of the oxide layer is gradually saturated. For example, when a solder having an oxide layer with a thickness of about 100 μm is acid-washed under the above-described conditions, the thickness of the oxide layer is reduced to 20 to 30 μm in about 5 minutes, and is then gradually reduced to 10 μm or less in about 15 minutes.

A method for polishing the surface of the solder is not particularly limited, either. For example, the solder sheet or wire may be polished by pulling it through abrasive paper held with an appropriate force while rolling it up. Alternatively, the solder may be polished by reciprocating abrasive paper in a direction perpendicular to a rolling up direction. However, as a matter of course, the roughness of abrasive paper to be used is selected so that the thickness of an oxide layer on the surface of the solder is reduced to 120 nm or less and the surface roughness (Ra) of the solder is reduced to 0.60 μm or less.

As described above, a solder alloy whose oxide layer thickness is as small as 120 nm or less and whose surface roughness (Ra) is as low as 0.60 μm or less can be produced by controlling its production conditions such as temperature and atmosphere and by, when the solder alloy is formed into a sheet or wire shape, performing rolling with a roll having a surface roughness of 0.30 μm or less, acid-washing, surface polishing, or two or more of them in combination.

<Solder Composition>

As described above, it is essential for the solder alloy according to the present invention to control its oxide layer thickness being 120 nm or less and to control its surface roughness (Ra) being 0.60 μm or less, but at the same time, its solder composition needs to be appropriately selected. That is, the solder alloy according to the present invention needs to have a composition within a desired range, more specifically any one of the following 9 compositions.

A first solder composition is a composition of a Bi-based alloy containing 85 mass % or more of Bi. A second solder composition is a composition as in the first Bi-based alloy which further contains 0.01 mass % or more but 13.5 mass % or less of Zn. A third solder composition is a composition as in the first Bi-based alloy which further contains 0.01 mass % or more but 12.0 mass % or less of Ag.

A fourth solder composition is a composition of a Bi-based alloy containing 40 mass % or more but less than 85 mass % of Bi and 60 mass % or less of Sn, wherein when an element or elements other than Bi and Sn are contained, content thereof is 5 mass % or less.

A fifth solder composition is a composition of a Pb-based alloy containing Pb as a main component and at least one of Sn, Ag, Cu, In, Te, and P as a second element group, wherein a total amount of Pb and the second element group is 80 mass % or more.

A sixth solder composition is a composition of an Sn-based alloy containing Sn as a main component and at least one of Ag, Sb, Cu, Ni, Ge, and P as a second element group, wherein a total amount of Sn and the second element group is 80 mass % or more.

A seventh solder composition is a composition of an Au-based alloy containing Au as a main component and at least one of Ge, Sn, and Si as a second element group, wherein a total amount of Au and the second element group is 90 mass % or more.

An eighth solder composition is a composition of an In-based alloy containing 40 mass % or more of In and at last one of Ag, Sn, Cu, Zn, and P.

A ninth solder composition is a composition of a Zn- or Sn-based alloy containing Zn and Sn in a total amount of 80 mass % or more but containing no Al.

Each of the 9 solder alloys having their respective compositions described above can be used as the solder alloy according to the present invention that is excellent in wettability and joinability and thus ensures high joint reliability by controlling the thickness of an oxide layer on its surface to be 120 nm or less and adjusting its surface roughness (Ra) to 0.60 μm or less.

An electronic device obtained by using the solder alloy according to the present invention to join various electronic components, such as semiconductor chips, to a circuit board can have very high durability even when used under severe environmental conditions where, for example, heat cycles are repeated. Therefore, the use of the solder alloy according to the present invention for soldering in various electronic devices for use under severe conditions, such as power semiconductor devices (e.g., thyristors and inverters), various controllers installed in cars and the like, and solar cells makes it possible to improve the reliability of these electronic devices.

### EXAMPLES

### Example 1

As raw materials, Bi, Zn, Ag, Sn, Pb, Cu, Au, In, Al, Ni, Sb, Ge, Te, Si, and P each having a purity of 99.9 mass % or more were prepared. When the raw materials were in the form of large slice or bulk, they were cut and pulverized into small pieces having a size of 3 mm or less by cutting and pulverization while attention was paid so that the composition of an alloy after melting would be uniform without varying depending on sampling site. Then, predetermined amounts of these raw materials were weighed and placed in a graphite crucible for a high-frequency melting furnace.

The crucible containing the raw materials was placed in the high-frequency melting furnace, and nitrogen was fed at a flow rate of 0.7 L/min or more per kilogram of the raw materials to suppress oxidation. In such a state, the melting furnace was turned on to heat and melt the raw materials. When started to melt, the raw material metals were well stirred with a mixing bar and uniformly mixed to prevent localized variations in composition. After the metals were confirmed to be sufficiently melted, a high-frequency power source was turned off, and the crucible was quickly taken out of the melting furnace, and the molten metal in the crucible was poured into a mold for solder master alloy. The mold had the same shape as that commonly used for producing solder master alloys.

In this way, solder master alloys different in the mixing ratio among the raw materials were prepared as Samples 1 to 44. The composition of each of the solder master alloys obtained as Samples 1 to 44 was analyzed with an ICP emission spectrometer (SHIMADZU S-8100). The obtained analysis results are shown as solder compositions in the following Tables 1 to 5.

It is to be noted that Samples 1 to 8 shown in Table 1 are Bi-based alloys having any one of the above-described first to fourth solder compositions, Samples 9 to 18 shown in Table 2 are Pb-based alloys having the above-described fifth solder composition, Samples 19 to 28 shown in Table 3 are Sn-based alloys having the above-described sixth solder composition, Samples 29 to 34 shown in Table 4 are Au-based alloys having the above-described seventh solder composition, Samples 35 to 42 shown in Table 5 are In-based alloys having the above-described eighth solder composition, and Samples 43 and 44 are Sn- or Zn-based alloys having the above-described ninth solder composition.

TABLE 1

Solder Composition (mass %)

| Samples | Bi | Zn | Ag | Sn |
|---|---|---|---|---|
| 1 | Balance | 2.0 | — | 5.0 |
| 2 | Balance | 2.7 | — | — |
| 3 | Balance | — | 2.5 | — |
| 4 | Balance | — | — | 30.0 |
| 5 | Balance | — | — | 29.8 |
| 6* | Balance | 20.1 | — | — |
| 7* | Balance | — | 19.9 | — |
| 8* | Balance | — | — | 70.2 |

(Note)
Samples marked with * are Comparative Examples.

TABLE 2

| | Solder Composition (mass %) | | | | | | | |
|---|---|---|---|---|---|---|---|---|
| Samples | Pb | Ag | Sn | Cu | In | Te | P | Bi |
| 9 | Balance | — | 3.0 | — | — | — | — | — |
| 10 | Balance | — | 5.2 | — | — | — | — | — |
| 11 | Balance | — | 10.1 | — | — | — | — | — |
| 12 | Balance | 2.5 | 2.0 | — | — | — | — | — |
| 13 | Balance | 2.5 | 5.0 | — | — | — | — | — |
| 14 | Balance | 2.0 | 10.1 | — | — | — | — | — |
| 15 | Balance | 2.5 | 2.0 | 0.10 | — | — | 0.06 | — |
| 16 | Balance | 2.5 | — | — | 5.1 | — | — | — |
| 17 | Balance | 2.4 | 2.1 | — | — | 0.05 | — | — |
| 18* | Balance | — | 5.1 | — | — | — | — | 21.0 |

(Note)
Sample marked with * is Comparative Example.

TABLE 3

| | Solder Composition (mass %) | | | | | | | |
|---|---|---|---|---|---|---|---|---|
| Samples | Sn | Ag | Cu | Ni | Sb | Ge | P | Bi |
| 19 | Balance | 3.5 | — | — | — | — | — | — |
| 20 | Balance | 5.0 | — | — | — | — | — | — |
| 21 | Balance | 10.1 | — | — | — | — | — | — |
| 22 | Balance | 3.5 | 0.5 | 0.06 | — | 0.01 | — | — |
| 23 | Balance | — | — | — | 3.5 | — | — | — |
| 24 | Balance | — | — | — | 8.5 | — | — | — |
| 25 | Balance | — | — | 0.60 | 7.0 | — | 0.05 | — |
| 26 | Balance | 3.0 | 0.5 | — | — | — | — | — |
| 27 | Balance | 1.0 | 0.2 | — | — | — | — | — |
| 28* | Balance | 5.0 | — | — | — | — | — | 21.2 |

(Note)
Sample marked with * is Comparative Example.

TABLE 4

Solder Composition (mass %)

| Samples | Au | Sn | Ge | Si | Bi |
|---|---|---|---|---|---|
| 29 | Balance | — | 12.2 | — | — |
| 30 | Balance | 19.9 | — | — | — |
| 31 | Balance | — | — | 1.0 | — |
| 32 | Balance | — | — | 2.0 | — |
| 33 | Balance | — | — | 3.2 | — |
| 34* | Balance | — | 12.6 | — | 11.3 |

(Note)
Sample marked with * is Comparative Example.

TABLE 5

| | Solder Composition (mass %) | | | | | | | |
|---|---|---|---|---|---|---|---|---|
| Samples | In | Ag | Sn | Cu | Zn | P | Bi | Pb |
| 35 | Balance | 3.0 | | — | — | — | — | — |
| 36 | Balance | 10.0 | | — | — | — | — | — |
| 37 | Balance | — | 3.0 | — | — | — | — | — |
| 38 | Balance | — | 48.2 | — | — | — | — | — |
| 39 | Balance | — | — | | 2.1 | — | — | — |
| 40 | Balance | — | — | 0.5 | — | — | — | — |
| 41 | Balance | — | — | 0.5 | — | 0.05 | — | — |
| 42* | Balance | — | — | — | — | — | 5.3 | — |
| 43 | — | — | Balance | — | 9.0 | — | — | — |
| 44* | — | — | 35.5 | — | Balance | — | — | 20.6 |

(Note)
Samples marked with * are Comparative Examples.

Then, each of the solder master alloys of Samples 1 to 44 shown in Table 1 to 5 was formed into a sheet shape by a rolling machine in the following manner to evaluate the workability of the solder alloy. Specifically, each of the solder master alloys (plate-shaped ingot with a thickness of 5 mm) was roughly rolled to have a thickness of 400 μm (warm rolling at a rolling temperature of 90° C.) while the feed rate of the ingot was adjusted. Then, all the Samples were finally subjected to finish rolling at room temperature using a reduction roll having a surface roughness (Ra) of 0.1 μm to have a thickness of 100 μm.

Each of the solder alloys rolled into a sheet in such a manner as described above was cut to have a width of 25 mm by slit processing. Then, each of the solder alloys was polished with three kinds of abrasive papers of different roughness (#240, #1000, #8000) in order, and was then buffed (abrasive grain: 0.1 μm) to have a predetermined surface roughness. Then, each of the solder alloys was acid-washed with dilute sulfuric acid for 1 to 10 minutes, washed with water to sufficiently remove the acid, further washed with ethanol, and then subjected to vacuum drying at ordinary temperature in a vacuum oven. It is to be noted that in a usual solder production process, surface polishing is often not performed, and an acid used in acid-washing is not limited to dilute sulfuric acid. However, in this example, the sheet-shaped solder alloys were produced under the above-described conditions purposely to adjust their oxide layer thickness or surface roughness.

Then, each of the thus obtained sheet-shaped solder alloys of Samples 1 to 44 was subjected to measurements of oxide layer thickness and surface roughness (Ra). The oxide layer thickness was measured using a field-emission-type Auger electron spectrometer (manufactured by ULVAC-PHI, Model: SAM-4300), and the surface roughness (Ra) was measured using a surface roughness tester (manufactured by TOKYO SEIMITSU CO., LTD., Model: SURFCOM 470A). The measurement results of oxide layer thickness and surface roughness (Ra) are shown in the following Tables 6 and 7.

Further, each of the sheet-shaped solder alloys of Samples 1 to 44 was subjected to evaluation of wettability (joinability) and evaluation of reliability by heat cycle test in the following manner. It is to be noted that the wettability or joinability of a solder does not depend on the shape of the solder, and therefore the solder to be evaluated may have any shape such as a wire or ball. However, in this example, each of the solder alloys was evaluated in the form of sheet.

<Evaluation of Wettability (Joinability)>

Each of the solder alloys formed into a sheet shape in the above-described manner was evaluated using a wettability tester (device name: atmosphere control-type wettability tester). Specifically, a heater unit of the wettability tester was doubly covered and heated to a heater preset temperature 50° C. higher than the melting point of each of the solder alloys while nitrogen was fed from four points around the heater unit at a flow rate of 12 L/min. After the temperature of the heater became stable at the preset temperature, a Cu substrate (thickness: about 0.70 mm) was set in the heater unit and heated for 25 seconds.

Then, each of the solder alloys of Samples was placed on the Cu substrate and heated for 25 seconds. After the completion of heating, the Cu substrate was removed from the heater unit and cooled by temporarily putting it in a place beside the heater unit where a nitrogen atmosphere was maintained. After sufficiently cooled, the Cu substrate was exposed to the atmosphere to observe a joint. The joint between each of the solder alloys of Samples and the Cu substrate was visually observed and evaluated according to the following criteria.

X (poor): Joining was not successful.

Δ (acceptable): Joining was successful but spreading of the solder was poor (the solder was not spread).

◯ (good): Joining was successful and spreading of the solder was good (the solder was thinly spread).

<Heat Cycle Test>

A heat cycle test was performed to evaluate the reliability of a solder joint. This test was performed using two samples per each of the solder alloys which had been successfully joined in the above-described wettability evaluation (i.e., samples evaluated as ◯ or Δ in the wettability evaluation). Specifically, in each of the Samples, two Cu substrates having the solder alloy joined thereto were subjected to a heat cycle test by repeating cycles each consisting of cooling at −55° C. and heating at +150° C. One of the two Cu substrates was subjected to the heat cycle test by repeating 300 cycles to observe a joint on the way, but the other one was subjected to the heat cycle test by repeating 500 cycles.

After subjected to the heat cycle test by repeating 300 or 500 cycles, each of the Cu substrate having the solder alloy joined thereto was embedded in a resin, and the cross section of the resin was polished to observe a joint surface with SEM (device name: HITACHI S-4800), and the joint surface was evaluated according to the following criteria.

X (poor): Separation of the joint surface or cracking in the solder was observed.

◯ (good): Such defects were not observed and the joint surface was maintained in its initial state.

The results of the heat cycle test are shown in the following Tables 6 and 7 together with the evaluation results of wettability.

TABLE 6

| | Oxide layer | Surface | | | |
|---|---|---|---|---|---|
| | thickness | roughness | | Heat cycle test | |
| Samples | (nm) | Ra (μm) | Wettability | 300 cycles | 500 cycles |
| 1 | 5.0 | 0.30 | ◯ | ◯ | ◯ |
| 2 | 5.0 | 0.30 | ◯ | ◯ | ◯ |
| 3 | 5.1 | 0.28 | ◯ | ◯ | ◯ |
| 4 | 5.2 | 0.30 | ◯ | ◯ | ◯ |
| 5* | 5.0 | 0.30 | ◯ | ◯ | ◯ |
| 6* | 4.6 | 0.30 | Δ | X | — |
| 7* | 5.0 | 0.24 | ◯ | X | — |
| 8* | 5.1 | 0.29 | ◯ | X | — |
| 9 | 5.0 | 0.30 | ◯ | ◯ | ◯ |
| 10 | 4.9 | 0.30 | ◯ | ◯ | ◯ |
| 11 | 5.0 | 0.30 | ◯ | ◯ | ◯ |
| 12 | 5.1 | 0.29 | ◯ | ◯ | ◯ |
| 13 | 5.0 | 0.28 | ◯ | ◯ | ◯ |
| 14 | 4.8 | 0.30 | ◯ | ◯ | ◯ |
| 15 | 5.1 | 0.30 | ◯ | ◯ | ◯ |
| 16 | 5.1 | 0.27 | ◯ | ◯ | ◯ |
| 17 | 4.7 | 0.30 | ◯ | ◯ | ◯ |
| 18* | 4.8 | 0.30 | Δ | X | — |
| 19 | 5.2 | 0.30 | ◯ | ◯ | ◯ |
| 20 | 5.0 | 0.30 | ◯ | ◯ | ◯ |
| 21 | 4.8 | 0.30 | ◯ | ◯ | ◯ |
| 22 | 5.2 | 0.29 | ◯ | ◯ | ◯ |
| 23 | 5.2 | 0.26 | ◯ | ◯ | ◯ |
| 24 | 5.0 | 0.30 | ◯ | ◯ | ◯ |
| 25 | 5.1 | 0.30 | ◯ | ◯ | ◯ |
| 26 | 5.1 | 0.30 | ◯ | ◯ | ◯ |
| 27 | 5.0 | 0.30 | ◯ | ◯ | ◯ |
| 28* | 5.1 | 0.30 | Δ | X | — |

(Note)
Sample marked with * is Comparative Example.

TABLE 7

| | Oxide layer | Surface | | | |
|---|---|---|---|---|---|
| | thickness | roughness | | Heat cycle test | |
| Samples | (nm) | Ra (μm) | Wettability | 300 cycles | 500 cycles |
| 29 | 1.0 | 0.29 | ◯ | ◯ | ◯ |
| 30 | 1.2 | 0.30 | ◯ | ◯ | ◯ |
| 31 | 1.1 | 0.30 | ◯ | ◯ | ◯ |
| 32 | 0.9 | 0.27 | ◯ | ◯ | ◯ |
| 33 | 1.1 | 0.29 | ◯ | ◯ | ◯ |
| 34* | 4.5 | 0.30 | ◯ | X | — |
| 35 | 5.2 | 0.30 | ◯ | ◯ | ◯ |
| 36 | 5.2 | 0.30 | ◯ | ◯ | ◯ |
| 37 | 5.1 | 0.30 | ◯ | ◯ | ◯ |
| 38 | 5.0 | 0.30 | ◯ | ◯ | ◯ |
| 39 | 4.9 | 0.28 | ◯ | ◯ | ◯ |
| 40 | 4.8 | 0.27 | ◯ | ◯ | ◯ |
| 41 | 5.1 | 0.30 | ◯ | ◯ | ◯ |
| 42* | 5.2 | 0.30 | Δ | X | — |
| 43 | 5.1 | 0.30 | ◯ | ◯ | ◯ |
| 44* | 5.2 | 0.28 | Δ | X | — |

(Note)
Samples marked with * are Comparative Examples.

As can be seen from the above Tables 6 and 7, the solder alloys according to the present invention of Samples 1 to 5 (Bi-based), Samples 9 to 17 (Pb-based), Samples 19 to 27 (Sn-based), Samples 29 to 33 (Au-based), Samples 35 to 41 (In-based), and Sample 43 (Sn-based) achieved good results for all the evaluation items. Specifically, the solder alloys according to the present invention had good wettability, and in addition, exhibited good joinability and reliability without causing defects such as cracking even after 500 cycles in the heat cycle test.

The reason why the solder alloys according to the present invention had good wettability can be considered to be that their compositions were within an appropriate range, and the presence of oxygen interfering with joining between an electronic component and a substrate was minimized by reducing the thickness of an oxide layer on a solder surface to 120 nm or less and adjusting surface roughness (Ra) to 0.60 μm or less. Also, the reason why the solder alloys according to the present invention exhibited high reliability can be considered to be that the above-described control of thickness of an oxide layer and adjustment of surface roughness (Ra) were performed, and in addition, connection was performed under conditions where the presence of oxygen was minimized.

On the other hand, the solder alloys of Samples 6 to 8 (Bi-based), Sample 18 (Pb-based), Sample 28 (Sn-based), Sample 34 (Au-based), Sample 42 (In-based), and Sample 44 (Zn-based) as Comparative Examples resulted in poor results because their solder compositions were not within an appropriate range. Specifically, Sample 6, Sample 18, Sample 28, Sample 42, and Sample 44 were poor in wettability. Further, in the heat cycle test, defects were observed in all the samples of Comparative Examples before 300 cycles.

### Comparative Example 1

The raw materials were blended to have the same compositions as the solder alloys according to the present invention prepared in Example 1, that is, Samples 1 to 4 shown in Table 1, Samples 9 to 17 shown in Table 2, Samples 19 to 27 shown in Table 3, Samples 29 to 33 shown in Table 4, Samples 35 to 41 and 43 shown in Table 5, and then formed into a sheet shape under the following conditions to prepare solder alloys of Comparative Examples.

Specifically, the raw materials were melted without introduction of nitrogen, each of the solder alloys was polished with abrasive paper (roughness: #220) before rough rolling, rough rolling was performed at a temperature 20° C. lower than the melting point of each of the solder alloys, finish rolling was performed at room temperature using a reduction roll having a surface roughness (Ra) of 0.5 μm, and polishing and acid-washing after rolling were not performed. The thus prepared sheet-shaped solder alloys were used as Samples 45 to 79 of Comparative Examples.

These Samples 45 to 79 were subjected to composition analysis, measurements of surface roughness and oxide layer thickness, wettability evaluation, and reliability evaluation in the same manner as in Example 1, and the results are shown in the following Table 8. The results of composition analysis of Samples 45 to 79 were the same as the solder compositions of Samples of Example 1 shown above in Table 1 to 5. For reference purposes, sample numbers in Tables 1 to 5 corresponding to Samples 45 to 79 are shown in the following Table 8.

TABLE 8

| | Sample | Oxide layer | Surface | | Heat cycle test | |
|---|---|---|---|---|---|---|
| | with same | thickness | roughness | Wett- | 300 | 500 |
| Samples | composition | (nm) | Ra (μm) | ability | cycles | cycles |
| 45* | Sample 1 | 130 | 0.70 | X | — | — |
| 46* | Sample 2 | 130 | 0.71 | X | — | — |
| 47* | Sample 3 | 128 | 0.73 | X | — | — |
| 48* | Sample 4 | 131 | 0.77 | X | — | — |
| 49* | Sample 9 | 101 | 0.84 | X | — | — |
| 50* | Sample 10 | 130 | 0.69 | X | — | — |
| 51* | Sample 11 | 132 | 0.68 | X | — | — |
| 52* | Sample 12 | 130 | 0.70 | X | — | — |
| 53* | Sample 13 | 126 | 0.74 | X | — | — |
| 54* | Sample 14 | 128 | 0.75 | X | — | — |
| 55* | Sample 15 | 148 | 0.52 | X | — | — |
| 56* | Sample 16 | 119 | 0.82 | X | — | — |
| 57* | Sample 17 | 143 | 0.53 | X | — | — |
| 58* | Sample 19 | 132 | 0.70 | X | — | — |
| 59* | Sample 20 | 132 | 0.70 | X | — | — |
| 60* | Sample 21 | 131 | 0.69 | X | — | — |
| 61* | Sample 22 | 132 | 0.70 | X | — | — |
| 62* | Sample 23 | 130 | 0.70 | X | — | — |
| 63* | Sample 24 | 109 | 0.87 | X | — | — |
| 64* | Sample 25 | 123 | 0.70 | X | — | — |
| 65* | Sample 26 | 135 | 0.70 | X | — | — |
| 66* | Sample 27 | 130 | 0.70 | X | — | — |
| 67* | Sample 29 | 10 | 0.80 | Δ | X | — |
| 68* | Sample 30 | 10 | 0.79 | Δ | X | — |
| 69* | Sample 31 | 11 | 0.78 | Δ | X | — |
| 70* | Sample 32 | 130 | 0.81 | Δ | X | — |
| 71* | Sample 33 | 9 | 0.83 | Δ | X | — |
| 72* | Sample 35 | 12 | 0.70 | X | — | — |
| 73* | Sample 36 | 130 | 0.70 | X | — | — |
| 74* | Sample 37 | 130 | 0.70 | X | — | — |
| 75* | Sample 38 | 141 | 0.55 | X | — | — |
| 76* | Sample 39 | 102 | 0.88 | X | — | — |
| 77* | Sample 40 | 126 | 0.70 | X | — | — |
| 78* | Sample 41 | 133 | 0.70 | X | — | — |
| 79* | Sample 43 | 131 | 0.70 | X | — | — |

(Note)
Samples marked with * are Comparative Examples.

As can be seen from Table 8, all the solder alloys of Samples 45 to 79 resulted in poor results. Specifically, none of Samples 45 to 79 had good wettability, and Samples 67 to 71 could achieve successful joining but caused defects before 300 cycles in the heat cycle test. It can be said that the reason why the solder alloys of Samples 45 to 79 resulted in such poor results was that one or both of their surface roughness and oxide layer thickness was/were not within appropriate ranges.

1. A solder alloy comprising 85 mass % or more of Bi and having an oxide layer thickness of 120 nm or less and a surface roughness (Ra) of 0.60 μm or less.

2. The solder alloy according to claim 1, comprising 0.01 mass % or more but 13.5 mass % or less of Zn.

3. The solder alloy according to claim 1, comprising 0.01 mass % or more but 12.0 mass % or less of Ag.

4. A solder alloy comprising 40 mass % or more but less than 85 mass % of Bi and 60 mass % or less of Sn and having an oxide layer thickness of 120 nm or less and a surface roughness (Ra) of 0.60 μm or less, wherein when an element or elements other than Bi and Sn are contained, content thereof is 5 mass % or less.

5. A solder alloy comprising Pb as a main component and at least one of Sn, Ag, Cu, In, Te, and P as a second element group and having an oxide layer thickness of 120 nm or less and a surface roughness (Ra) of 0.60 m or less, wherein a total amount of Pb and the second element group is 80 mass % or more.

6. A solder alloy comprising Sn as a main component and at least one of Ag, Sb, Cu, Ni, Ge, and P as a second element group and having an oxide layer thickness of 120 nm or less and a surface roughness (Ra) of 0.60 rm or less, wherein a total amount of Sn and the second element group is 80 mass % or more.

7. A solder alloy comprising Au as a main component and at least one of Ge, Sn, and Si as a second element group and having an oxide layer thickness of 120 nm or less and a surface roughness (Ra) of 0.60 μm or less, wherein a total amount of Au and the second element group is 90 mass % or more.

8. A solder alloy comprising 40 mass % or more of In and at least one of Ag, Sn, Cu, Zn, and P and having an oxide layer thickness of 120 nm or less and a surface roughness (Ra) of 0.60 μm or less.

9. A solder alloy comprising Zn and Sn in a total amount of 80 mass % or more but comprising no Al and having an oxide layer thickness of 120 nm or less and a surface roughness (Ra) of 0.60 μm or less.

10. An electronic device comprising an electronic component joined with the solder alloy according to claim 1.

11. An electronic device comprising an electronic component joined with the solder alloy according to claim 2.

12. An electronic device comprising an electronic component joined with the solder alloy according to claim 3.

13. An electronic device comprising an electronic component joined with the solder alloy according to claim 4.

14. An electronic device comprising an electronic component joined with the solder alloy according to claim 5.

15. An electronic device comprising an electronic component joined with the solder alloy according to claim 6.

16. An electronic device comprising an electronic component joined with the solder alloy according to claim 7.

17. An electronic device comprising an electronic component joined with the solder alloy according to claim 8.

18. An electronic device comprising an electronic component joined with the solder alloy according to claim 9.
